(19) United States
(12) Patent Application Publication
(10) Pub. No.: US 2022/0200663 A1
(43) Pub. Date: Jun. 23, 2022

(54) PROCESSING CIRCUIT MODULE AND METHOD FOR MANUFACTURING NONCONTACT COMMUNICATION MEDIUM

(71) Applicant: FUJIFILM CORPORATION, Tokyo (JP)

(72) Inventor: Eiichiro KATAOKA, Kanagawa (JP)

(21) Appl. No.: 17/551,205

(22) Filed: Dec. 15, 2021

(30) Foreign Application Priority Data
Dec. 22, 2020 (JP) 2020-212862

(51) Int. Cl. H04B 5/00; G06K 19/07; G06K 19/077; H01L 23/528; H01L 23/66

(52) U.S. Cl. CPC H04B 5/0081; G06K 19/0723; G06K 19/077; H01L 2223/6677; H01L 23/66; H04B 5/0031; H04B 5/0062; H01L 23/528

(57) ABSTRACT

A processing circuit module includes a lead frame including a pair of leads electrically connectable to one end and the other end of an antenna coil of a substrate on which the antenna coil configured to induce power with application of a magnetic field from an outside is formed, and a processing circuit that is electrically connected to the pair of leads. The lead frame and the processing circuit are modularized.

### CROSS-REFERENCE TO RELATED APPLICATIONS

This application claims priority under 35 USC 119 from Japanese Patent Application No. 2020-212862 filed on Dec. 22, 2020, the disclosure of which is incorporated by reference herein.

### BACKGROUND

### 1. Technical Field

A technique of the present disclosure relates to a processing circuit module and a method for manufacturing a noncontact communication medium.

### 2. Related Art

JP2013-235363A discloses an antenna sheet for a dual card. In the antenna sheet described in JP2013-235363A, a surface of a base resin film has conductive layers of a pattern of the antenna coil and a pattern of an internal connection terminal. A card base material made of thermoplastic resin is laminated on both surfaces of the base resin film. The card base material has a recess into which a dual interface IC module is fitted, and a terminal exposure hole that reaches a front surface of the internal connection terminal. In the antenna sheet described in JP2013-235363A, the shape of the pattern exposed in the recess is an antenna dummy pattern disposed in a card short-side direction.

JP2009-080843A discloses a semiconductor device that is mounted on a card body comprising an antenna coil for performing wireless communication with an external transmission and reception device. The semiconductor device described in JP2009-080843A has a wiring board, a first connection terminal, a second connection terminal, a semiconductor chip, a third connection terminal, a fourth connection terminal, and a capacitor. The wiring board has a main surface and a back surface on an opposite side to the main surface. The first connection terminal is provided on the main surface of the wiring board and is electrically connected to one end of the antenna coil through a first conductive material. The second connection terminal is provided on the main surface of the wiring board and is electrically connected to the other end of the antenna coil through the first conductive material. The semiconductor chip is mounted on the main surface of the wiring board, is further electrically connected to the first connection terminal and the second connection terminal, and performs data processing. The third connection terminal is provided on the main surface of the wiring board and is electrically connected to the first connection terminal by wiring of the wiring board. The fourth connection terminal is provided on the main surface of the wiring board and is electrically connected to the second connection terminal by wiring. The capacitor has one end electrically connected to the third connection terminal and the other end electrically connected to the fourth connection terminal by a second conductive material to form a resonance circuit. In the semiconductor device described in JP2009-080843A, the first connection terminal and the second connection terminal are disposed on different sides of the semiconductor chip.

JP2020-505658A discloses an integrated circuit (IC) module for a smart card having both a contact interface and a noncontact interface. The integrated circuit (IC) module for smart card described in JP2020-505658A has a non-conductive substrate that has a first surface and a second surface, and has a plurality of single-bond holes and a pair of multi-bond holes extending from the first surface to the second surface, a plurality of conductive contact pads that are disposed on the first surface of the substrate and include a first pair, a first IC chip that is disposed on the second surface of the substrate, a plurality of first conductor elements that pass through the single-bonding holes and the pair of multi-bonding holes and electrically connect at least some of the contact pads to the first IC chip, and a sealing material that is deposited on the first IC chip, the first conductor elements, and the first pair of the contact pads. The first conductor elements include a first pair of the first conductor elements that respectively pass through the pair of multi-bonding holes, and electrically connect the first pair of the contact pads to the first IC chip. The sealing material deposited on the first pair of the contact pads divides each of the pair of multi-bond holes into a first bonding channel and an adjacent second bonding channel respectively bordering a first bonding region and an adjacent second bonding region on the first pair of the contact pads, the first bonding region is sealed with the sealing material, and the second bonding region for providing a front surface to establish electrical connection to the first IC chip is exposed through the second bonding channel. The sealing material partitions the first bonding region and the second bonding region from each other without providing a substrate between the first bonding region and the second bonding region.

### SUMMARY

An embodiment according to the technique of the present disclosure provides a processing circuit module capable of increasing the strength of connection between an antenna coil and a processing circuit on a substrate compared to a case where the processing circuit is directly connected to the antenna coil.

A first aspect according to the technique of the present disclosure is a processing circuit module comprising a lead frame including a pair of leads electrically connectable to one end and the other end of an antenna coil of a substrate on which the antenna coil configured to induce power with application of a magnetic field from an outside is formed, and a processing circuit electrically connected to the pair of leads, in which the lead frame and the processing circuit are modularized.

A second aspect according to the technique of the present disclosure is the processing circuit module according to the first aspect, in which the processing circuit and the lead frame are sealed with resin.

A third aspect according to the technique of the present disclosure is the processing circuit module according to the first aspect or the second aspect, in which the pair of leads protrudes from the processing circuit module.

A fourth aspect according to the technique of the present disclosure is the processing circuit module according to any one of the first aspect to the third aspect, in which the processing circuit has an internal capacitor, the processing circuit module further comprises an external capacitor that is externally attached to the processing circuit and composes a resonance circuit configured to resonate at a predetermined resonance frequency with application of the magnetic field, along with the internal capacitor and the antenna coil, in which the processing circuit, the lead frame, and the external capacitor are modularized.

A fifth aspect according to the technique of the present disclosure is the processing circuit module according to the fourth aspect, in which the processing circuit, the lead frame, and the external capacitor are sealed with resin.

A sixth aspect according to the technique of the present disclosure is the processing circuit module according to the fourth aspect or the fifth aspect, in which the processing circuit is an IC chip, and the IC chip and the external capacitor are fixed to the lead frame.

A seventh aspect according to the technique of the present disclosure is the processing circuit module according to any one of the first aspect to the sixth aspect, in which the substrate is a flexible type substrate.

An eighth aspect according to the technique of the present disclosure is the processing circuit module according to any one of the first aspect to the seventh aspect, in which the pair of leads is soldered to the one end and the other end of the antenna coil.

A ninth aspect according to the technique of the present disclosure is a method for manufacturing a noncontact communication medium comprising producing a processing circuit module by modularizing a lead frame including a pair of leads electrically connectable to one end and the other end of an antenna coil of a substrate, on which the antenna coil configured to induce power with application of a magnetic field from an outside is formed, and a processing circuit electrically connected to the pair of leads, and mounting the processing circuit module on the substrate by electrically connecting the pair of leads to the one end and the other end.

A tenth aspect according to the technique of the present disclosure is the method for manufacturing a noncontact communication medium according to the ninth aspect, in which the processing circuit module is produced by sealing the processing circuit and the lead frame using resin.

An eleventh aspect according to the technique of the present disclosure is the method for manufacturing a noncontact communication medium according to the ninth aspect or the tenth aspect, in which the pair of leads protrude from the processing circuit module.

A twelfth aspect according to the technique of the present disclosure is the method for manufacturing a noncontact communication medium according to any one of the ninth aspect to the eleventh aspect, in which the processing circuit has an internal capacitor, and the processing circuit module is produced by modularizing an external capacitor that is externally attached to the processing circuit, the processing circuit, and the lead frame, the external capacitor composing a resonance circuit configured to resonate at a predetermined resonance frequency with application of the magnetic field, along with the internal capacitor and the antenna coil.

A thirteenth aspect according to the technique of the present disclosure is the method for manufacturing a noncontact communication medium according to the twelfth aspect, in which the processing circuit module is produced by sealing the external capacitor, the processing circuit, and the lead frame using resin.

A fourteenth aspect according to the technique of the present disclosure is the method for manufacturing a noncontact communication medium according to the twelfth aspect or the thirteenth aspect, in which the processing circuit is an IC chip, and the IC chip and the external capacitor are fixed to the lead frame.

A fifteenth aspect according to the technique of the present disclosure is the method for manufacturing a noncontact communication medium according to any one of the ninth aspect to the fourteenth aspect, in which the substrate is a flexible type substrate.

A sixteenth aspect according to the technique of the present disclosure is the method for manufacturing a noncontact communication medium according to any one of the ninth aspect to the fifteenth aspect, in which the processing circuit module is mounted on the substrate by soldering the pair of leads to the one end and the other end of the antenna coil.

### BRIEF DESCRIPTION OF THE DRAWINGS

Exemplary embodiments of the present invention will be described in detail based on the following figures, wherein:

FIG. 1 is a schematic perspective view showing an example of the appearance of a magnetic tape cartridge according to an embodiment;

FIG. 2 is a schematic perspective view showing an example of the structure of a rear right end portion inside a lower case of the magnetic tape cartridge according to the embodiment;

FIG. 3 is a side cross-sectional view showing an example of a support member provided on an inner surface of the lower case of the magnetic tape cartridge according to the embodiment;

FIG. 4 is a schematic configuration diagram showing an example of the hardware configuration of the magnetic tape drive according to the embodiment;

FIG. 5 is a schematic perspective view showing an example of an aspect in which a magnetic field is discharged from a lower side of the magnetic tape cartridge according to the embodiment by a noncontact reading and writing device;

FIG. 6 is a conceptual diagram showing an example of an aspect in which a magnetic field is applied from the noncontact reading and writing device to a cartridge memory in the magnetic tape cartridge according to the embodiment;

FIG. 7 is a bottom view showing an example of a back surface structure of the cartridge memory according to the embodiment;

FIG. 8 is a top view showing an example of a front surface structure of the cartridge memory according to the embodiment;

FIG. 9 is an explanatory view showing an example of a manufacturing method for a processing circuit module according to the embodiment;

FIG. 10 is a schematic end view of the processing circuit module shown in FIG. 9 taken along the line A-A;

FIG. 11 is a schematic end view of the processing circuit module shown in FIG. 9 taken along the line B-B;

FIG. 12 is a schematic circuit diagram showing an example of the circuit configuration of the cartridge memory according to the embodiment;

FIG. 13 is a flowchart illustrating an example of a flow of a manufacturing and mounting step of the processing circuit module according to the embodiment;

FIG. 14 is a schematic end view showing a modification example of the processing circuit module; and

FIG. 15 is a conceptual diagram showing a modification example of an inclination angle of the cartridge memory in the magnetic tape cartridge.

### DETAILED DESCRIPTION

First, terms that are used in the following description will be described.

CPU is an abbreviation for “Central Processing Unit”. RAM is an abbreviation for “Random Access Memory”. NVM is an abbreviation for “Non-Volatile Memory”. ROM is an abbreviation for “Read Only Memory”. EEPROM is an abbreviation for “Electrically Erasable and Programmable Read Only Memory”. SSD is an abbreviation for “Solid State Drive”. USB is an abbreviation for “Universal Serial Bus”. ASIC is an abbreviation for “Application Specific Integrated Circuit”. PLD is an abbreviation for “Programmable Logic Device”. FPGA is an abbreviation for “Field-Programmable Gate Array”. SoC is an abbreviation for “System-on-a-Chip”. IC is an abbreviation for “Integrated Circuit”. RFID is an abbreviation for “Radio Frequency Identifier”. LTO is an abbreviation for “Linear Tape-Open”.

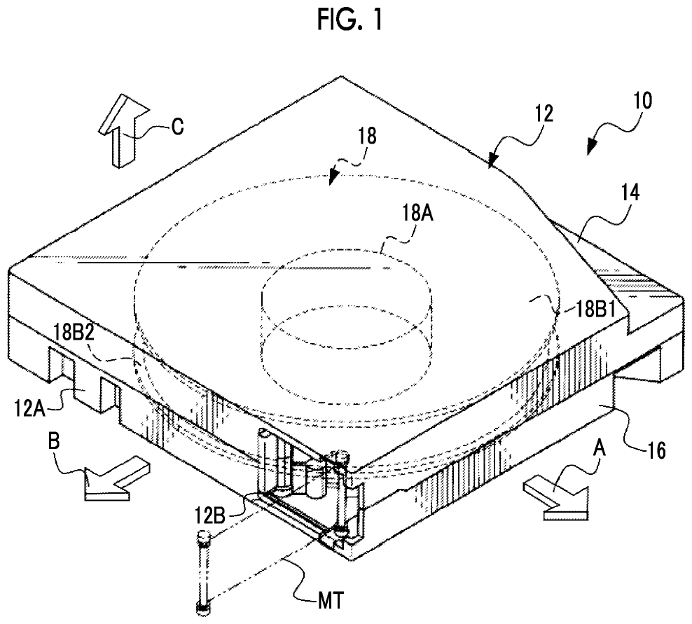

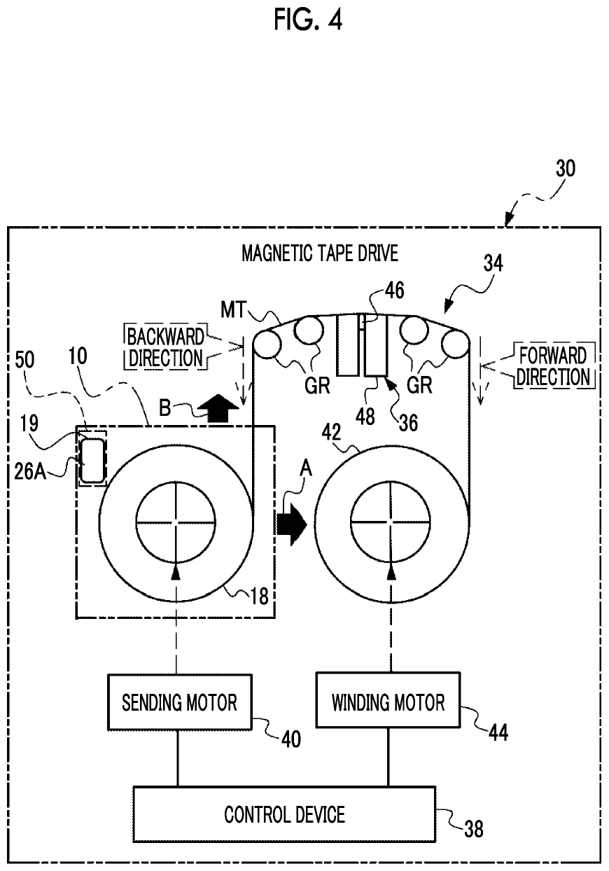

In the following description, for convenience of description, in FIG. 1, a loading direction of a magnetic tape cartridge 10 on a magnetic tape drive 30 (see FIG. 4) is indicated by an arrow A, a direction of the arrow A is referred to a front direction of the magnetic tape cartridge 10, and a side in the front direction of the magnetic tape cartridge 10 is referred to as a front side of the magnetic tape cartridge 10. In the following description on the structure, “front” indicates the front side of the magnetic tape cartridge 10.

In the following description, for convenience of description, in FIG. 1, a direction of an arrow B perpendicular to the direction of the arrow A is referred to as a right direction, and a side in the right direction of the magnetic tape cartridge 10 is referred to as a right side of the magnetic tape cartridge 10. In the following description on the structure, “right” indicates the right side of the magnetic tape cartridge 10.

In the following description, for convenience of description, in FIG. 1, a direction perpendicular to the direction of the arrow A and the direction of the arrow B is indicated by an arrow C, a direction of the arrow C is referred to as an upper direction of the magnetic tape cartridge 10, and a side in the upper direction of the magnetic tape cartridge 10 is referred to as an upper side of the magnetic tape cartridge 10. In the following description on the structure, “upper” indicates the upper side of the magnetic tape cartridge 10.

In the following description, for convenience of description, in FIG. 1, a direction opposite to the front direction of the magnetic tape cartridge 10 is referred to as a rear direction of the magnetic tape cartridge 10, and a side in the rear direction of the magnetic tape cartridge 10 is referred to as a rear side of the magnetic tape cartridge 10. In the following description on the structure, “rear” indicates the rear side of the magnetic tape cartridge 10.

In the following description, for convenience of description, in FIG. 1, a direction opposite to the upper direction of the magnetic tape cartridge 10 is referred to as a lower direction of the magnetic tape cartridge 10, and a side in the lower direction of the magnetic tape cartridge 10 is referred to as a lower side of the magnetic tape cartridge 10. In the following description on the structure, “lower” indicates the lower side of the magnetic tape cartridge 10.

In the following description, LTO will be described as an example of the standard of the magnetic tape cartridge 10. In the following description, although description will be provided on an assumption that the specification shown in Table 1 described below is applied to LTO according to the technique of the present disclosure, this is merely an example, and LTO according to the technique of the present disclosure may conform to the specification of IBM3592 magnetic tape cartridge.

TABLE 1

| Communication Command | ISO14443 | |
|---|---|---|
| Classification | Standard | LTO Specification |
| REQA to SELECT Series | 86 or 91 μs | 86 or 91 μs |
| | | (“1172/13.56 (MHz)” |
| | | or “1236/13.56 (MHz)”) |
| READ Series | Unspecified | 86 or 91 μs |
| | | (“1172/13.56 (MHz)” |
| | | or “1236/13.56 (MHz)”) |
| WRITE Series | Unspecified | about 10.02 ms |
| | | (“135828/13.56 (MHz)” |
| | | or “135892/13.56 (MHz)”) |

In Table 1, “REQA to SELECT Series” means a polling command described below. In “REQA to SELECT Series”, at least a “Request A” command, a “Request SN” command, and a “Select” command are included. “Request A” is a command that inquires a cartridge memory about what type of cartridge memory is. In the embodiment, “Request A” is one kind; however, the technique of the present disclosure is not limited thereto, and “Request A” may be a plurality of kinds. “Request SN” is a command that inquires the cartridge memory about a serial number. “Select” is a command that notifies the cartridge memory beforehand of preparation of reading and writing. READ Series is a command corresponding to a read-out command described below. WRITE Series is a command corresponding to a write-in command described below.

As shown in FIG. 1 as an example, the magnetic tape cartridge 10 has a substantially rectangular shape in plan view, and comprises a box-shaped case 12. The case 12 is formed of resin, such as polycarbonate, and comprises an upper case 14 and a lower case 16. The upper case 14 and the lower case 16 are bonded by welding (for example, ultrasonic welding) and screwing in a state in which a lower peripheral edge surface of the upper case 14 and an upper peripheral edge surface of the lower case 16 are brought into contact with each other. A bonding method is not limited to welding and screwing, and other bonding methods may be used.

Inside the case 12, a cartridge reel 18 is rotatably housed. The cartridge reel 18 comprises a reel hub 18A, an upper flange 18B1, and a lower flange 18B2. The reel hub 18A is formed in a cylindrical shape. The reel hub 18A is a shaft center portion of the cartridge reel 18, has a shaft center direction along an up-down direction of the case 12, and is disposed in a center portion of the case 12. Each of the upper flange 18B1 and the lower flange 18B2 is formed in an annular shape. A center portion in plan view of the upper flange 18B1 is fixed to an upper end portion of the reel hub 18A, and a center portion in plan view of the lower flange 18B2 is fixed to a lower end portion of the reel hub 18A. A magnetic tape MT is wound around an outer peripheral surface of the reel hub 18A, and an end portion in a width direction of the magnetic tape MT is held by the upper flange 18B1 and the lower flange 18B2. The reel hub 18A and the lower flange 18B2 may be molded integrally.

An opening 12B is formed on a front side of a right wall 12A of the case 12. The magnetic tape MT is pulled out from the opening 12B.

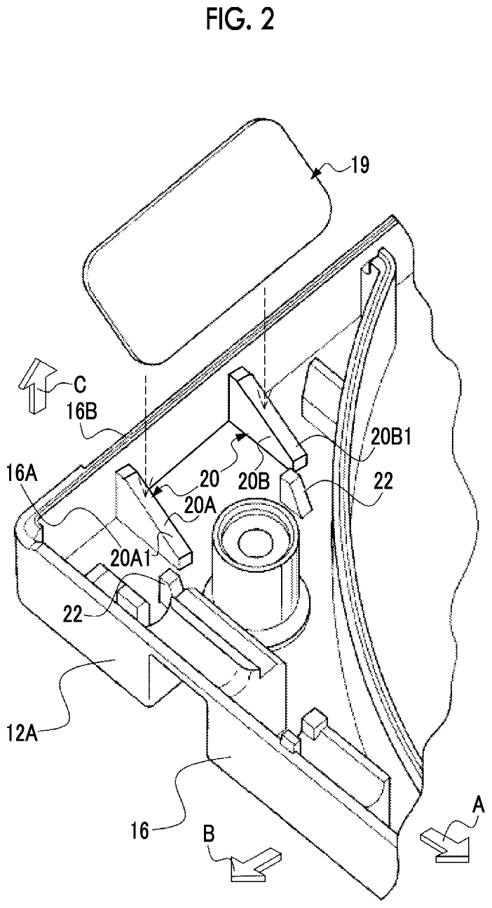

As shown in FIG. 2 as an example, a cartridge memory 19 is housed in a rear right end portion of the lower case 16. In the embodiment, a so-called passive type RFID tag is employed as the cartridge memory 19.

Management information is stored in the cartridge memory 19. The management information is information for managing the magnetic tape cartridge 10. Examples of the management information include identification information capable of specifying the magnetic tape cartridge 10, a recording capacity of the magnetic tape MT, the outline of information (hereinafter, referred to as “recorded information”) recorded on the magnetic tape MT, items of the recorded information, and information indicating a recording format and the like of the recorded information.

The cartridge memory 19 performs communication with an external device (not shown) in a noncontact manner. Examples of the external device include a reading and writing device that is used in a production process of the magnetic tape cartridge 10 and a reading and writing device (for example, a noncontact reading and writing device 50 shown in FIGS. 4 to 6) that is used in a magnetic tape drive (for example, the magnetic tape drive 30 shown in FIG. 4).

The external device performs reading and writing of various kinds of information to the cartridge memory 19 in a noncontact manner. Although details will be described below, the cartridge memory 19 generates power with electromagnetic application to a magnetic field from the external device. Then, the cartridge memory 19 operates using the generated power and performs transfer of various kinds of information with the external device by performing communication with the external device through the magnetic field. A communication system may be, for example, a system conforming to a known standard, such as ISO14443 or ISO18092, or may be a system conforming to the LTO Specification of ECMA319.

As shown in FIG. 2 as an example, a support member 20 is provided on an inner surface of a bottom plate 16A in the rear right end portion of the lower case 16. The support member 20 is a pair of inclined mounts that supports the cartridge memory 19 from below in an inclined state. A pair of inclined mounts is a first inclined mount 20A and a second inclined mount 20B. The first inclined mount 20A and the second inclined mount 20B are disposed at an interval in a right-left direction of the case 12 and are modularized in an inner surface of a rear wall 16B of the lower case 16 and the inner surface of the bottom plate 16A. The first inclined mount 20A has an inclined surface 20A1, and the inclined surface 20A1 is inclined downward from the inner surface of the rear wall 16B toward the inner surface of the bottom plate 16A. An inclined surface 20B1 is also inclined downward from the inner surface of the rear wall 16B toward the inner surface of the bottom plate 16A.

In front of the support member 20, a pair of position restriction ribs 22 is disposed at an interval in the right-left direction. A pair of position restriction ribs 22 is provided upright on the inner surface of the bottom plate 16A and restricts a position of a lower end portion of the cartridge memory 19 in a state of being disposed on the support member 20.

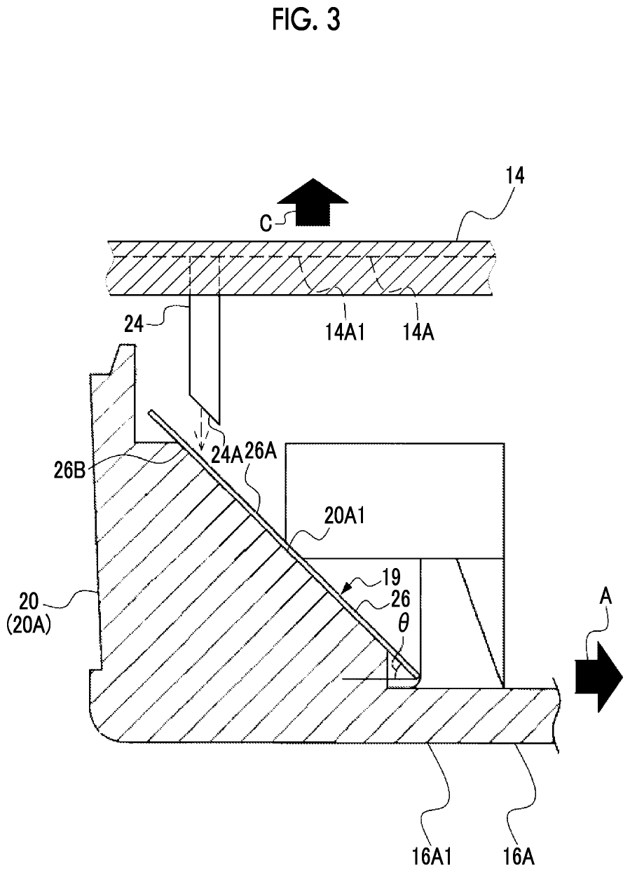

As shown in FIG. 3 as an example, a reference surface 16A1 is formed on an outer surface of the bottom plate 16A. The reference surface 16A1 is a plane. Here, the plane indicates a surface parallel to a horizontal plane in a case where the lower case 16 is placed on the horizontal plane such that the bottom plate 16A turns toward a lower side. An inclination angle θ of the support member 20, that is, an inclination angle of each of the inclined surface 20A1 and the inclined surface 20B1 is 45 degrees with respect to the reference surface 16A1. The inclination angle of 45 degrees is merely an example, and may be in a range of “0 degrees <inclination angle θ<45 degrees” or may be equal to or greater than 45 degrees.

The cartridge memory 19 comprises a substrate 26. The substrate 26 is an example of a “substrate” according to the technique of the present disclosure. The substrate 26 is a flexible type substrate and has a substantially rectangular flat plate shape. The substrate 26 has two surfaces in a thickness direction, that is, a front surface 26A and a back surface 26B. The substrate 26 is placed on the support member 20 such that the back surface 26B of the substrate 26 turns toward a lower side, and the support member 20 supports the back surface 26B of the substrate 26 from below. A part of the back surface 26B of the substrate 26 is in contact with the inclined surface of the support member 20, that is, the inclined surfaces 20A1 and 20B1, and a front surface 26A of the substrate 26 is exposed to an inner surface 14A1 side of a top plate 14A.

The upper case 14 comprises a plurality of ribs 24. A plurality of ribs 24 are disposed at intervals in the right-left direction of the case 12. A plurality of ribs 24 are provided to protrude downward from the inner surface 14A1 of the top plate 14A of the upper case 14, and a distal end surface 24A of each rib 24 has an inclined surface corresponding to the inclined surfaces 20A1 and 20B1. That is, the distal end surface 24A of each rib 24 is inclined at 45 degrees with respect to the reference surface 16A1.

In a case where the upper case 14 is bonded to the lower case 16 as described above in a state in which the cartridge memory 19 is disposed on the support member 20, the distal end surface 24A of each rib 24 comes into contact with the substrate 26 from the front surface 26A side, and the substrate 26 is pinched by the distal end surface 24A of each rib 24 and the inclined surface of the support member 20. With this, a position in an up-down direction of the cartridge memory 19 is restricted by the ribs 24.

As shown in FIG. 4 as an example, the magnetic tape drive 30 comprises a transport device 34, a reading head 36, and a control device 38. The magnetic tape cartridge 10 is loaded into the magnetic tape drive 30. The magnetic tape drive 30 is a device that pulls out the magnetic tape MT from the magnetic tape cartridge 10 and reads recorded information from the pulled-out magnetic tape MT using the reading head 36 by a linear serpentine method. In the embodiment, in order words, reading of the recorded information indicates reproduction of the recorded information.

The control device 38 controls the entire magnetic tape drive 30. In the embodiment, although the control device 38 is realized by an ASIC, the technique of the present disclosure is not limited thereto. For example, the control device 38 may be realized by an FPGA. Alternatively, the control device 38 may be realized by a computer including a CPU, a ROM, and a RAM. In addition, the control device 38 may be realized by combining two or more of an ASIC, an FPGA, and a computer. That is, the control device 38 may be realized by a combination of a hardware configuration and a software configuration.

The transport device 34 is a device that selectively transports the magnetic tape MT in a forward direction and a backward direction, and comprises a sending motor 40, a winding reel 42, a winding motor 44, a plurality of guide rollers GR, and the control device 38.

The sending motor 40 rotationally drives the cartridge reel 18 in the magnetic tape cartridge 10 under the control of the control device 38. The control device 38 controls the sending motor 40 to control a rotation direction, a rotation speed, rotation torque, and the like of the cartridge reel 18.

The winding motor 44 rotationally drives the winding reel 42 under the control of the control device 38. The control device 38 controls the winding motor 44 to control a rotation direction, a rotation speed, rotation torque, and the like of the winding reel 42.

In a case where the magnetic tape MT is wound around the winding reel 42, the sending motor 40 and the winding motor 44 are rotated by the control device 38 such that the magnetic tape MT runs in the forward direction. Rotation speeds, rotation torque, and the like of the sending motor 40 and the winding motor 44 are adjusted depending on a speed of the magnetic tape MT wound around the winding reel 42.

In a case where the magnetic tape MT is rewound to the cartridge reel 18, the sending motor 40 and the winding motor 44 are rotated by the control device 38 such that the magnetic tape MT runs in the backward direction. Rotation speeds, rotation torque, and the like of the sending motor 40 and the winding motor 44 are adjusted depending on a speed of the magnetic tape MT wound around the winding reel 42.

The rotation speed, the rotation torque, and the like of each of the sending motor 40 and the winding motor 44 are adjusted in this manner, whereby tension in a predetermined range is applied to the magnetic tape MT. Here, the predetermined range indicates, for example, a range of tension obtained from a computer simulation and/or a test with a real machine as a range of tension in which data can be read from the magnetic tape MT by the reading head 36.

In the embodiment, although the rotation speed, the rotation torque, and the like of each of the sending motor 40 and the winding motor 44 are controlled such that the tension of the magnetic tape MT is controlled, the technique of the present disclosure is not limited thereto. For example, the tension of the magnetic tape MT may be controlled using a dancer roller or may be controlled by drawing the magnetic tape MT to a vacuum chamber.

Each of a plurality of guide rollers GR is a roller that guides the magnetic tape MT. A running path of the magnetic tape MT is determined by separately disposing a plurality of guide rollers GR at positions straddling over the reading head 36 between the magnetic tape cartridge 10 and the winding reel 42.

The reading head 36 comprises a reading element 46 and a holder 48. The reading element 46 is held by the holder 48 to come into contact with the magnetic tape MT during running, and reads recorded information from the magnetic tape MT transported by the transport device 34.

The magnetic tape drive 30 comprises the noncontact reading and writing device 50. The noncontact reading and writing device 50 is an example of an “outside” according to the technique of the present disclosure. The noncontact reading and writing device 50 is disposed to confront the back surface 26B of the cartridge memory 19 below the magnetic tape cartridge 10 in a state in which the magnetic tape cartridge 10 is loaded. The state in which the magnetic tape cartridge 10 is loaded into the magnetic tape drive 30 indicates, for example, a state in which the magnetic tape cartridge 10 reaches a position determined in advance as a position where reading of recorded information from the magnetic tape MT by the reading head 36 starts.

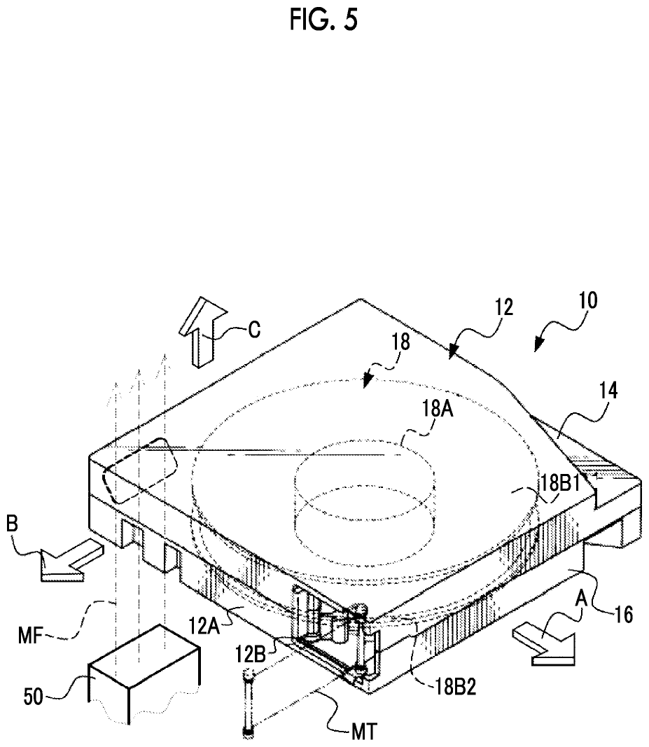

As shown in FIG. 5 as an example, the noncontact reading and writing device 50 emits a magnetic field MF from below the magnetic tape cartridge 10 toward the cartridge memory 19. The magnetic field MF passes through the cartridge memory 19. The magnetic field MF is an example of a “magnetic field” according to the technique of the present disclosure.

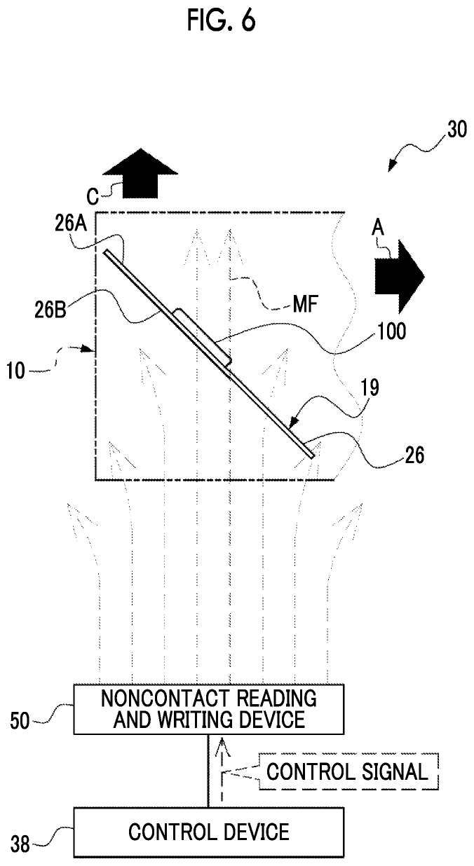

As shown in FIG. 6 as an example, the noncontact reading and writing device 50 is connected to the control device 38. The control device 38 outputs a control signal for controlling the cartridge memory 19 to the noncontact reading and writing device 50. The noncontact reading and writing device 50 emits the magnetic field MF toward the cartridge memory 19 in compliance with the control signal input from the control device 38. The magnetic field MF passes through the cartridge memory 19 from the back surface 26B side to the front surface 26A side.

The noncontact reading and writing device 50 spatially transmits a command signal to the cartridge memory 19 under the control of the control device 38. Though described below in detail, the command signal is a signal indicating a command to the cartridge memory 19. In a case where the command signal is spatially transmitted from the noncontact reading and writing device 50 to the cartridge memory 19, the command signal is included in the magnetic field MF in compliance with an instruction from the control device 38 by the noncontact reading and writing device 50. In other words, the command signal is superimposed on the magnetic field MF. That is, the noncontact reading and writing device 50 transmits the command signal to the cartridge memory 19 through the magnetic field MF under the control of the control device 38.

A processing circuit module 100 is mounted on the front surface 26A of the cartridge memory 19. The processing circuit module 100 is soldered to the front surface 26A. The processing circuit module 100 is an example of a “processing circuit module” according to the technique of the present disclosure.

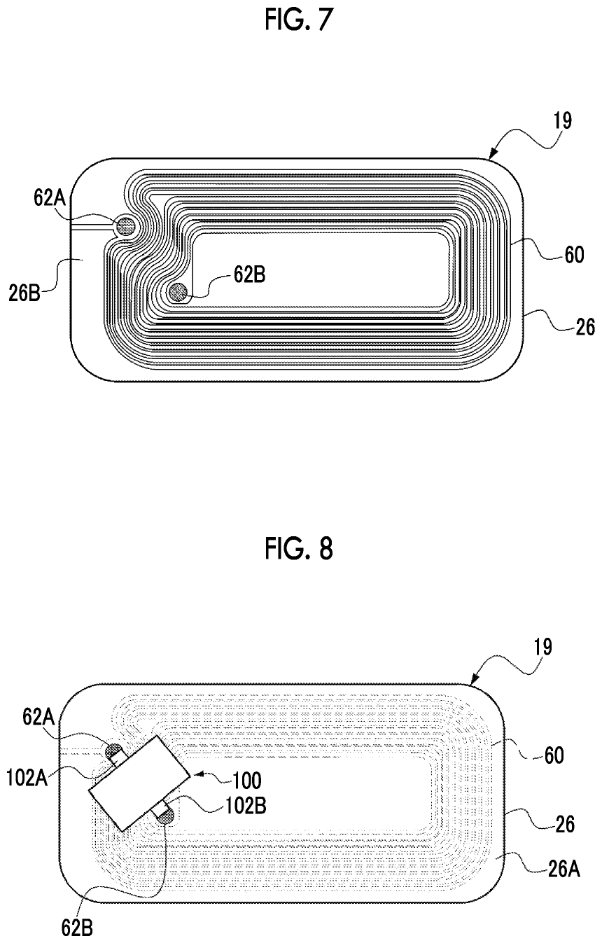

As shown in FIG. 7 as an example, a coil 60 is formed in a loop shape on the back surface 26B of the cartridge memory 19. Here, as a material of the coil 60, copper foil is employed. The copper foil is merely an example, and for example, other kinds of conductive materials, such as aluminum foil, may be used. The coil 60 induces an induced current with application of the magnetic field MF (see FIGS. 5 and 6) from the noncontact reading and writing device 50. The coil 60 is an example of an “antenna coil” according to the technique of the present disclosure.

A first conduction portion 62A and a second conduction portion 62B are provided on the back surface 26B of the cartridge memory 19. The first conduction portion 62A and the second conduction portion 62B have solder and electrically connect both end portions of the coil 60 to the processing circuit module 100 (see FIGS. 6 and 8) on the front surface 26A. The first conduction portion 62A and the second conduction portion 62B are an example of “one end and the other end of an antenna coil” according to the technique of the present disclosure.

As shown in FIG. 8 as an example, on the front surface 26A of the cartridge memory 19, the processing circuit module 100 is electrically connected to the first conduction portion 62A and the second conduction portion 62B. Specifically, a first lead 102A that is one lead of a pair of leads protruding from the processing circuit module 100 is soldered to the first conduction portion 62A, and a second lead 102B that is the other lead of a pair of leads is soldered to the second conduction portion 62B. The first lead 102A and the second lead 102B are an example of “a pair of leads” according to the technique of the present disclosure.

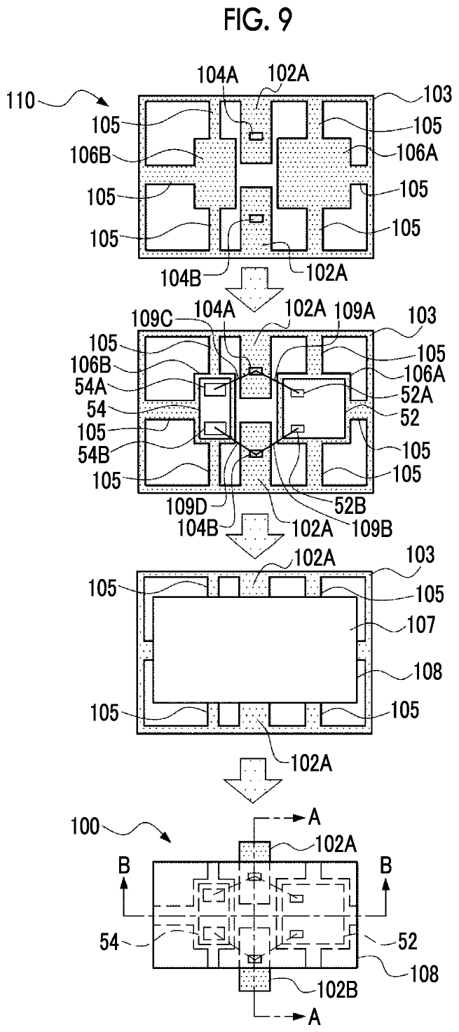

FIG. 9 shows an example of a manufacturing method for the processing circuit module 100. As shown in FIG. 9 as an example, the processing circuit module 100 is manufactured using a lead frame 110 having electric conductivity. The lead frame 110 is formed of a metal plate. Examples of metal composing the metal plate include copper, a copper alloy, and a 42 alloy. The lead frame 110 includes a frame 103, the first lead 102A, the second lead 102B, a first die pad 106A, a second die pad 106B, and a plurality of support portions 105. The lead frame 110 is an example of a “lead frame” according to the technique of the present disclosure.

The frame 103 is formed in a rectangular frame shape. The first die pad 106A and the second die pad 106B are disposed in parallel at the center of the frame 103, and are supported on the frame 103 by a plurality of (in the example shown in FIG. 9, six) support portions 105. The first lead 102A and the second lead 102B are formed to extend from the frame 103 toward a gap between the first die pad 106A and the second die pad 106B. The first lead 102A is provided with a first plated layer 104A, and the second lead 102B is provided with a second plated layer 104B. The first plated layer 104A and the second plated layer 104B are portions on which plating is performed. Examples of plating include silver plating and palladium plating.

An IC chip 52 is fixed to the first die pad 106A by solder, an adhesive, or the like. The IC chip 52 has a positive electrode terminal 52A and a negative electrode terminal 52B. The positive electrode terminal 52A is bonded and connected to the first plated layer 104A provided on the first lead 102A using a wire 109A. The negative electrode terminal 52B is bonded and connected to the second plated layer 104B provided on the second lead 102B using a wire 109B. Examples of a material of the wires 109A and 109B include conductive materials, such as gold, copper, and aluminum. The IC chip 52 is an example of a “processing circuit” and an “IC chip” according to the technique of the present disclosure.

An external capacitor 54 is fixed to the second die pad 106B. Examples of a material for fixing the external capacitor 54 to the second die pad 106B include solder and an adhesive. The external capacitor 54 has a pair of electrodes 54A and 54B. The electrode 54A is bonded and connected to the first plated layer 104A provided on the second lead 102B, for example, using a wire 109C consisting of gold, copper, aluminum, or the like. The electrode 54B is bonded and connected to the second plated layer 104B provided on the second lead 102B, for example, using a wire 109D consisting of gold, copper, aluminum, or the like. Accordingly, the external capacitor 54 is externally attached to the IC chip 52 in parallel. The external capacitor 54 is an example of an “external capacitor” according to the technique of the present disclosure.

The lead frame 110 is sealed with resin 107. The IC chip 52 and the external capacitor 54 are connected to the lead frame 110. The resin 107 is resin having insulation. As the resin 107, for example, epoxy resin, polyimide resin, phenol resin, or vinyl chloride resin can be used. The resin 107 is an example of “resin” according to the technique of the present disclosure.

After sealing with the resin 107, the frame 103 and the support portions 105 are cut off. With this, the lead frame 110, the IC chip 52, and the external capacitor 54 are modularized. That is, the processing circuit module 100 having a sealed section 108 where the IC chip 52 and the external capacitor 54 are sealed along with the lead frame 110, the first lead 102A, and the second lead 102B is obtained.

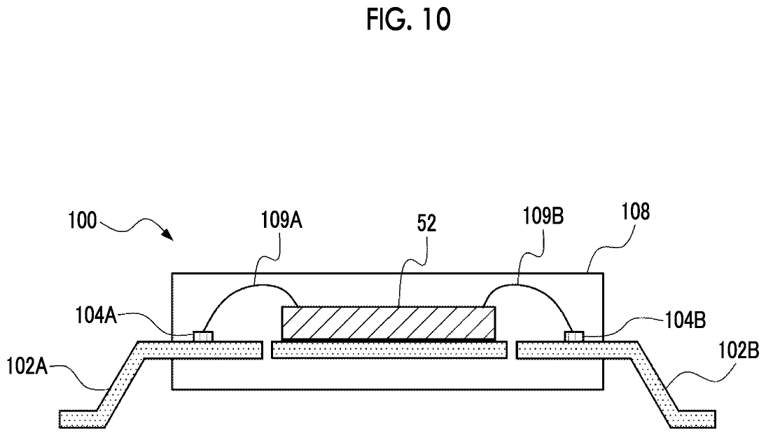

FIG. 10 is a schematic end view of the processing circuit module 100 shown in FIG. 9 taken along the line A-A. As shown in FIG. 10 as an example, the processing circuit module 100 has a shape in which the first lead 102A and the second lead 102B protrude from the sealed section 108. The first lead 102A and the second lead 102B are used as connection terminals for connecting the IC chip 52 and the external capacitor 54 to the coil 60. In general, in a case where the IC chip 52 is directly connected to the first conduction portion 62A and the second conduction portion 62B, since the positive electrode terminal 52A and the negative electrode terminal 52B of the IC chip 52 are smaller than the first lead 102A and the second lead 102B, the IC chip 52 is bonded and connected to the first conduction portion 62A and the second conduction portion 62B by thin wires. In contrast, according to the embodiment, the IC chip 52 is soldered to the coil 60 through the first lead 102A and the second lead 102B.

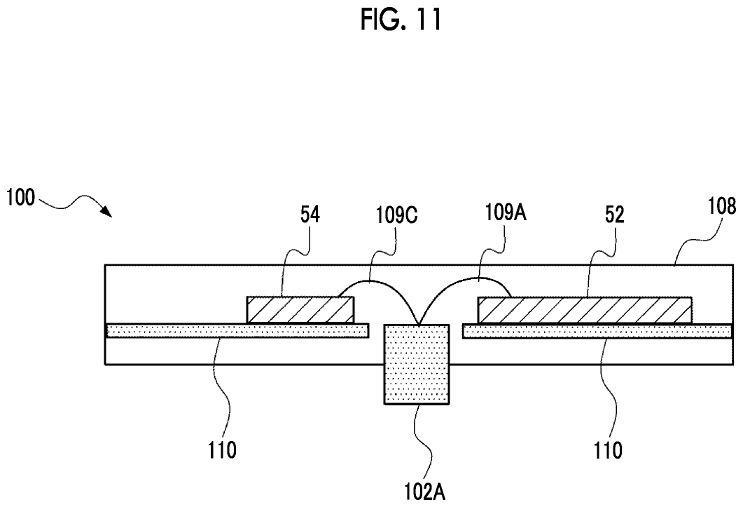

FIG. 11 is a schematic end view of the processing circuit module 100 shown in FIG. 9 taken along the line B-B. As shown in FIG. 11 as an example, the lead frame 110, the IC chip 52, and the external capacitor 54 are modularized as the processing circuit module 100.

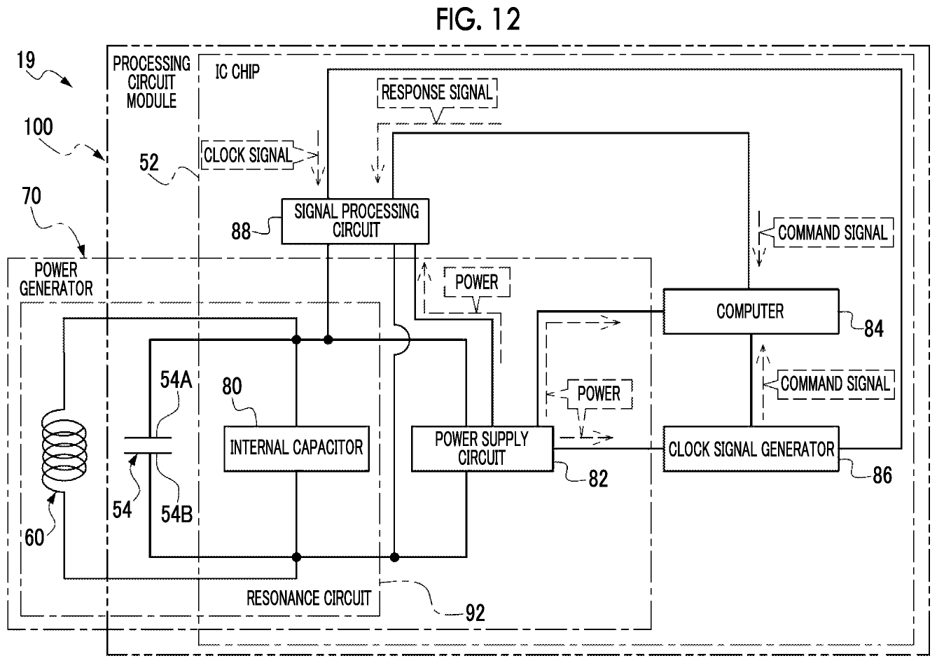

As shown in FIG. 12 as an example, the IC chip 52 comprises an internal capacitor 80, a power supply circuit 82, a computer 84, a clock signal generator 86, and a signal processing circuit 88. The IC chip 52 is a general-use IC chip that is usable for purposes other than the magnetic tape cartridge 10, and functions as an arithmetic device for a magnetic tape cartridge in a case where a program for a magnetic tape cartridge is installed thereon. The internal capacitor 80 is an example of an “internal capacitor” according to the technique of the present disclosure.

The cartridge memory 19 comprises a power generator 70. The power generator 70 generates power with application of the magnetic field MF from the noncontact reading and writing device 50 to the coil 60. Specifically, the power generator 70 generates alternating-current power using a resonance circuit 92, converts the generated alternating-current power into direct-current power, and outputs the direct-current power. The resonance circuit 92 is an example of a “resonance circuit” according to the technique of the present disclosure.

The power generator 70 has the resonance circuit 92 and the power supply circuit 82. The resonance circuit 92 comprises the external capacitor 54, the coil 60, and the internal capacitor 80. The internal capacitor 80 is a capacitor incorporated in the IC chip 52, and the power supply circuit 82 is also a circuit incorporated in the IC chip 52. The internal capacitor 80 is connected in parallel with the coil 60. The internal capacitor 80 is connected in parallel with the external capacitor 54.

The external capacitor 54 is a capacitor externally attached to the IC chip 52. The IC chip 52 is a general-use IC chip that is intrinsically usable for purposes different from the magnetic tape cartridge 10. For this reason, the capacitance of the internal capacitor 80 may not be enough to realize a resonance frequency required for the cartridge memory 19 used in the magnetic tape cartridge 10.

Accordingly, in the cartridge memory 19, the external capacitor 54 is post-attached to the IC chip 52 as a capacitor having a capacitance value necessary in making the resonance circuit 92 resonate at a predetermined resonance frequency with the application of the magnetic field MF. A frequency corresponding to the predetermined resonance frequency is, for example, 13.56 MHz, and may be appropriately decided depending on the specification or the like of the cartridge memory 19 and/or the noncontact reading and writing device 50. The capacitance of the external capacitor 54 is determined based on a measured value of the capacitance of the internal capacitor 80. 13.56 MHz is an example of a “predetermined resonance frequency” according to the technique of the present disclosure.

The power supply circuit 82 has a rectification circuit, a smoothing circuit, and the like. The rectification circuit is a full-wave rectification circuit having a plurality of diodes. The full-wave rectification circuit is merely an example, and a half-wave rectification circuit may be used. The smoothing circuit includes a capacitor and a resistor. The power supply circuit 82 converts the alternating-current power input from the resonance circuit 92 into direct-current power and supplies the converted direct-current power (hereinafter, simply referred to as “power”) to various drive elements in the IC chip 52. Examples of various drive elements include the computer 84, the clock signal generator 86, and the signal processing circuit 88. In this way, power is supplied to various drive elements in the IC chip 52 by the power generator 70, whereby the IC chip 52 operates using power generated by the power generator 70.

The computer 84 comprises a CPU, an NVM, and a RAM (all are not shown). The program for a magnetic tape cartridge and the management information are stored in the NVM. The CPU controls the operation of the cartridge memory 19 by reading the program from the NVM and executing the program on the RAM.

Specifically, the CPU selectively executes polling processing, read-out processing, and write-in processing in response to the command signal input from the signal processing circuit 88. The polling processing is processing of establishing communication between the cartridge memory 19 and the noncontact reading and writing device 50, and is executed, for example, as preparation processing in a pre-stage of the read-out processing and the write-in processing. The read-out processing is processing of reading out the management information and the like from the NVM. The write-in processing is processing of writing the management information and the like in the NVM. All of the polling processing, the read-out processing, and the write-in processing (hereinafter, referred to as various kinds of processing in a case where there is no need for distinction) are executed by the CPU in association with the clock signals generated by the clock signal generator 86. That is, the CPU executes various kinds of processing at a processing speed corresponding to the clock frequency.

The clock signal generator 86 generates a clock signal and outputs the clock signal to the computer 84. The computer 84 operates in association with the clock signal input from the clock signal generator 86.

The signal processing circuit 88 is connected to the resonance circuit 92. The signal processing circuit 88 has a decoding circuit and an encoding circuit (both are not shown). The decoding circuit of the signal processing circuit 88 extracts and decodes a command signal from the magnetic field MF received by the coil 60 and outputs the command signal to the computer 84. The computer 84 outputs a response signal to the command signal to the signal processing circuit 88. That is, the computer 84 executes processing according to the command signal input from the signal processing circuit 88 and outputs a processing result as a response signal to the signal processing circuit 88. In the signal processing circuit 88, in a case where the response signal is input from the computer 84, the encoding circuit of the signal processing circuit 88 encodes the response signal to modulate the response signal and outputs the response signal to the resonance circuit 92. The resonance circuit 92 transmits the response signal input from the encoding circuit of the signal processing circuit 88 to the noncontact reading and writing device 50 through the magnetic field MF. That is, in a case where the response signal is transmitted from the cartridge memory 19 to the noncontact reading and writing device 50, the response signal is included in the magnetic field MF. In other words, the response signal is superimposed on the magnetic field MF.

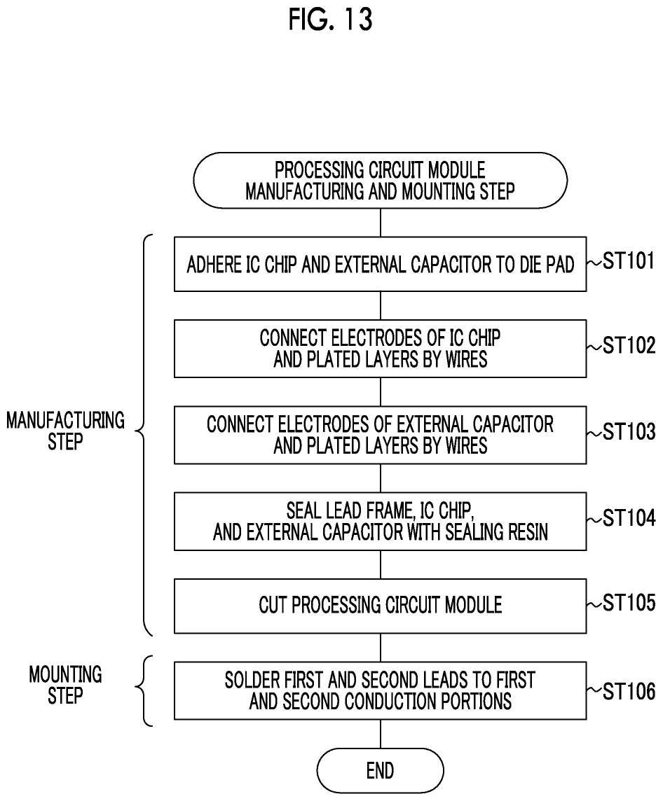

Next, the operations of the processing circuit module 100 according to the embodiment will be described referring to FIG. 13.

A processing circuit module manufacturing and mounting step shown in FIG. 13 as an example includes a manufacturing step and a mounting step. In the manufacturing step, first, in Step ST101, the IC chip 52 is adhered to the first die pad 106A, and the external capacitor 54 is adhered to the second die pad 106B. Thereafter, the manufacturing step progresses to Step ST102.

In Step ST102, the positive electrode terminal 52A of the IC chip 52 and the first plated layer 104A are bonded and connected by the wire 109A. The negative electrode terminal 52B of the IC chip 52 and the second plated layer 104B are bonded and connected by the wire 109B. Thereafter, the manufacturing step progresses to Step ST103.

In Step ST103, the electrode 54A of the external capacitor 54 and the first plated layer 104A are bonded and connected by the wire 109C. The electrode 54B of the external capacitor 54 and the second plated layer 104B are bonded and connected by the wire 109D. Thereafter, the manufacturing step progresses to Step ST104.

In Step ST104, the lead frame 110, the IC chip 52, and the external capacitor 54 are sealed with the resin 107. Thereafter, the manufacturing step progresses to Step ST105.

In Step ST105, the frame 103 and the support portions 105 are cut off, whereby the processing circuit module 100 is cut. Thereafter, the processing circuit module manufacturing and mounting step progresses to the mounting step of mounting the processing circuit module 100 on the substrate 26.

In the mounting step, in Step ST106, the first lead 102A and the second lead 102B protruding the processing circuit module 100 are soldered to the first conduction portion 62A and the second conduction portion 62B. With this, the processing circuit module manufacturing and mounting step ends.

As described above, the processing circuit module 100 comprises the lead frame 110 including the first lead 102A and the second lead 102B, and the IC chip 52. The first lead 102A and the second lead 102B are electrically connectable to the first conduction portion 62A and the second conduction portion 62B provided in the coil 60 of the substrate 26 on which the coil 60 configured to induce power with application of the magnetic field MF from the noncontact reading and writing device 50 is formed. The IC chip 52 is electrically connected to the first lead 102A and the second lead 102B. The lead frame 110 and the IC chip 52 are modularized as the processing circuit module 100. Therefore, according to this configuration, it is possible to increase the strength of connection between the antenna coil and the processing circuit on the substrate compared to a case where the processing circuit is directly connected to the antenna coil.

The IC chip 52 and the lead frame 110 are sealed with the resin 107. Therefore, according to this configuration, it is possible to protect the connection between the IC chip 52 and the lead frame 110 inside the processing circuit module 100.

The first lead 102A and the second lead 102B protrude from the processing circuit module 100. Therefore, according to this configuration, it is possible to easily connect the processing circuit module 100 to the first conduction portion 62A and the second conduction portion 62B compared to a case where the first lead 102A and the second lead 102B are disposed inside the processing circuit module 100.

The IC chip 52 has the internal capacitor 80. The processing circuit module 100 further comprises the external capacitor 54 that is externally attached to the IC chip 52. The external capacitor 54 composes the resonance circuit 92 configured to resonate at the predetermined resonance frequency with application of the magnetic field MF, along with the internal capacitor 80 and the coil 60. The IC chip 52, the lead frame 110, and the external capacitor 54 are modularized as the processing circuit module 100. Therefore, according to this configuration, it is possible to reduce the number of components that are mounted on the substrate 26, compared to a case where the IC chip 52 and the external capacitor 54 are separately mounted on the substrate 26.

The IC chip 52, the lead frame 110, and the external capacitor 54 are sealed with the resin 107. Therefore, according to this configuration, it is possible to protect the connection between the IC chip 52 and the lead frame 110 and the connection between the external capacitor 54 and the lead frame 110 inside the processing circuit module 100.

The IC chip 52 and the external capacitor 54 are fixed to the lead frame 110. Therefore, according to this configuration, the IC chip 52 and the external capacitor 54 do not deviate with respect to the lead frame 110.

The substrate 26 is a flexible type substrate. Therefore, according to this configuration, even though the substrate 26 is bent, it is possible to maintain the connection of the IC chip 52 and the external capacitor 54 to the coil 60.

The first lead 102A and the second lead 102B are soldered to the first conduction portion 62A and the second conduction portion 62B provided in the coil 60. Therefore, according to this configuration, it is possible to improve the strength of connection of the IC chip 52 and/or the external capacitor 54 to the coil 60 compared to a case where the IC chip 52 and/or the external capacitor 54 is bonded and connected to the first conduction portion 62A and the second conduction portion 62B using wires.

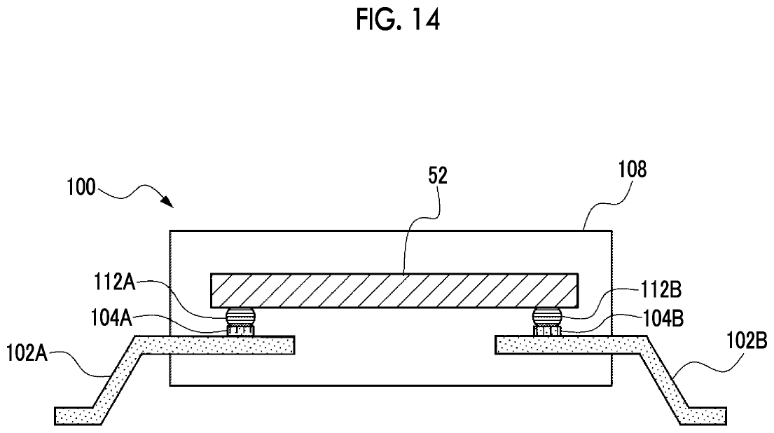

In the above-described embodiment, although a form example where the positive electrode terminal 52A and the negative electrode terminal 52B of the IC chip 52 are bonded and connected to the first plated layer 104A and the second plated layer 104B through the wire 109A and 109B, respectively, has been described, the technique of the present disclosure is not limited thereto. As shown in FIG. 14 as an example, the positive electrode terminal 52A and the negative electrode terminal 52B of the IC chip 52 may be melted and connected to the first plated layer 104A and the second plated layer 104B through a solder ball 112A and a solder ball 112B provided in the IC chip 52.

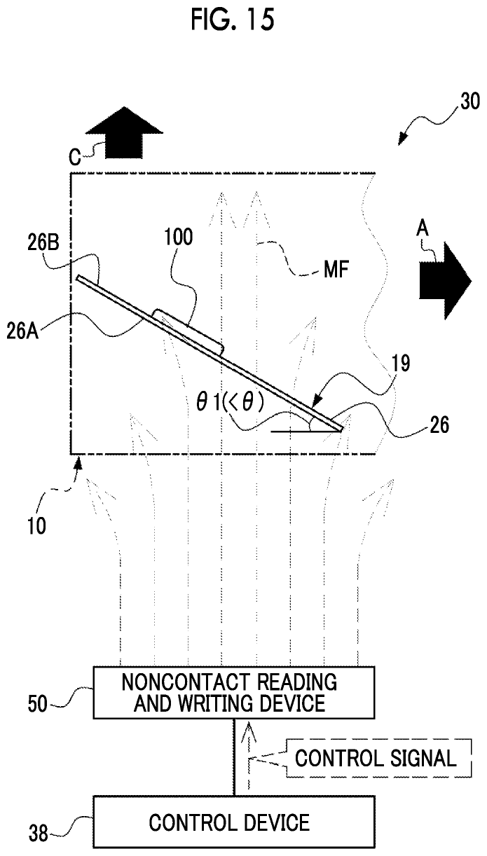

In the above-described embodiment, although 45 degrees have been exemplified as the inclination angle θ, the technique of the present disclosure is not limited thereto. As shown in FIG. 15 as an example, an inclination angle θ1 smaller than the inclination angle θ may be employed as the inclination angle with respect to the reference surface 16A1 of the cartridge memory 19. An example of the inclination angle θ1 is 30 degrees. Since the inclination angle θ1 is an angle smaller than the inclination angle θ, it is possible to make a large number of lines of magnetic force pass through the coil 60 (see FIG. 7) compared to the case of the inclination angle θ. As a result, the coil 60 can obtain a large induced current in a state in which the magnetic tape cartridge 10 is loaded into the magnetic tape drive 30 compared to the case of the inclination angle θ.

The content of the above description and the content of the drawings are detailed description of portions according to the technique of the present disclosure, and are merely examples of the technique of the present disclosure. For example, the above description relating to configuration, function, operation, and advantageous effects is description relating to configuration, function, operation, and advantageous effects of the portions according to the technique of the present disclosure. Thus, it is needless to say that unnecessary portions may be deleted, new elements may be added, or replacement may be made to the content of the above description and the content of the drawings without departing from the gist of the technique of the present disclosure. Furthermore, to avoid confusion and to facilitate understanding of the portions according to the technique of the present disclosure, description relating to common technical knowledge and the like that does not require particular description to enable implementation of the technique of the present disclosure is omitted from the content of the above description and the content of the drawings.

In the specification, “A and/or B” is synonymous with “at least one of A or B”. That is, “A and/or B” may refer to A alone, B alone, or a combination of A and B. Furthermore, in the specification, a similar concept to “A and/or B” applies to a case in which three or more matters are expressed by linking the matters with “and/or”.

All cited documents, patent applications, and technical standards described in the specification are incorporated by reference in the specification to the same extent as in a case where each individual cited document, patent application, or technical standard is specifically and individually indicated to be incorporated by reference.

What is claimed is:

1. A processing circuit module comprising:
a lead frame including a pair of leads electrically connectable to one end and the other end of an antenna coil of a substrate on which the antenna coil configured to induce power with application of a magnetic field from an outside is formed; and
a processing circuit that is electrically connected to the pair of leads,
wherein the lead frame and the processing circuit are modularized.

2. The processing circuit module according to claim 1,
wherein the processing circuit and the lead frame are sealed with resin.

3. The processing circuit module according to claim 1,
wherein the pair of leads protrudes from the processing circuit module.

4. The processing circuit module according to claim 1,
wherein the processing circuit has an internal capacitor,
the processing circuit module further comprises:
an external capacitor that is externally attached to the processing circuit and composes a resonance circuit configured to resonate at a predetermined resonance frequency with application of the magnetic field, along with the internal capacitor and the antenna coil, and
the processing circuit, the lead frame, and the external capacitor are modularized.

5. The processing circuit module according to claim 4,
wherein the processing circuit, the lead frame, and the external capacitor are sealed with resin.

6. The processing circuit module according to claim 4, further comprising:
an IC chip,
wherein the processing circuit is mounted in the IC chip, and
the IC chip and the external capacitor are fixed to the lead frame.

7. The processing circuit module according to claim 1,
wherein the substrate is a flexible type substrate.

8. The processing circuit module according to claim 1,
wherein the pair of leads is soldered to the one end and the other end of the antenna coil.

9. A method for manufacturing a noncontact communication medium, the method comprising:
producing a processing circuit module by modularizing a lead frame including a pair of leads electrically connectable to one end and the other end of an antenna coil of a substrate, on which the antenna coil configured to induce power with application of a magnetic field from an outside is formed, and a processing circuit electrically connected to the pair of leads; and
mounting the processing circuit module on the substrate by electrically connecting the pair of leads to the one end and the other end.

10. The method for manufacturing a noncontact communication medium according to claim 9,
wherein the processing circuit module is produced by sealing the processing circuit and the lead frame using resin.

11. The method for manufacturing a noncontact communication medium according to claim 9,
wherein the pair of leads protrudes from the processing circuit module.

12. The method of manufacturing a noncontact communication medium according to claim 9,
wherein the processing circuit has an internal capacitor, and
the processing circuit module is produced by modularizing an external capacitor that is externally attached to the processing circuit, the processing circuit, and the lead frame, the external capacitor composing a resonance circuit configured to resonate at a predetermined resonance frequency with application of the magnetic field, along with the internal capacitor and the antenna coil.

13. The method of manufacturing a noncontact communication medium according to claim 12,
wherein the processing circuit module is produced by sealing the external capacitor, the processing circuit, and the lead frame using resin.

14. The method of manufacturing a noncontact communication medium according to claim 12,
wherein the processing circuit is an IC chip, and
the IC chip and the external capacitor are fixed to the lead frame.

15. The method of manufacturing a noncontact communication medium according to claim 9,
wherein the substrate is a flexible type substrate.

16. The method of manufacturing a noncontact communication medium according to claim 9,
wherein the processing circuit module is mounted on the substrate by soldering the pair of leads to the one end and the other end of the antenna coil.
